(19) United States
(12) Patent Application Publication
(10) Pub. No.: US 2012/0178266 A1
(43) Pub. Date: Jul. 12, 2012

(54) COMPOSITIONS AND METHODS OF USE FOR FORMING TITANIUM-CONTAINING THIN FILMS

(75) Inventors: Peter Nicholas Heys, Crewe (GB); Rajesh Odedra, Altrincham (GB); Andrew Kingsley, Newton (GB)

(73) Assignee: SIGMA-AIDRICH CO. LLC, ST. LOUIS, MO (US)

(21) Appl. No.: 13/386,109

(22) PCT Filed: Jul. 19, 2010
(86) PCT No.: PCT/US10/42384

§ 371 Date: Mar. 29, 2012

Related U.S. Application Data
(60) Provisional application No. 61/227,123, filed on Jul. 21, 2009.

(51) Int. Cl. H01L 21/314; C09D 5/25

(52) U.S. Cl. 438/785; 106/1.05; 257/E21.266

(57) ABSTRACT

Compositions and methods for forming titanium-containing thin films are provided. The compositions comprise at least one precursor selected from the group consisting of (methylcyclopentadienyl)Ti(NMe₂)₃, (ethylcyclopentadienyl)Ti(NMe₂)₃, (isopropylcyclopentadienyl)Ti(NMe₂)₃, (methylcyclopentadienyl)Ti(NEt₂)₃, (methylcyclopentadienyl)Ti(NMeEt)₃, (ethylcyclopentadienyl)Ti(NMeEt)₃ and (methylcyclopentadienyl)Ti(OMe)₃; and at least one liquification co-factor other than the at least one precursor; wherein the at least one liquification co-factor is present in amount sufficient to co-act with the at least one precursor, and in combination with the at least one precursor, forms a liquid composition.

### CROSS-REFERENCE TO RELATED APPLICATION

This patent claims the benefit of U.S. provisional application Ser. No. 61/227,123, filed on 21 Jul. 2009. The disclosure of U.S. provisional application is incorporated by reference in its entirety.

### FIELD OF THE INVENTION

The present invention relates to titanium-containing compositions and methods of use in thin film deposition.

### BACKGROUND OF THE INVENTION

Various organometallic precursors are used to form high-κ dielectric thin metal films for use in the semiconductor industry. Various deposition processes are used to form the metal films, such as chemical vapor deposition (“CVD”) or atomic layer deposition (“ALD”), also known as atomic layer epitaxy.

CVD is a chemical process whereby precursors are deposited on a substrate to form a solid thin film. In a typical CVD process, the precursors are passed over a substrate (wafer) within a low pressure or ambient pressure reaction chamber. The precursors react and/or decompose on the substrate surface creating a thin film of deposited material. Volatile by-products are removed by gas flow through the reaction chamber. The deposited film thickness can be difficult to control because it depends on coordination of many parameters such as temperature, pressure, gas flow volumes and uniformity, chemical depletion effects and time.

ALD is a chemical process which separates the precursors during the reaction. The first precursor is passed over the substrate producing a monolayer on the substrate. Any excess unreacted precursor is pumped out of the reaction chamber. A second precursor is then passed over the substrate and reacts with the first precursor, forming a second monolayer of film over the first-formed film on the substrate surface. This cycle is repeated to create a film of desired thickness. ALD film growth is self-limited and based on surface reactions, creating uniform depositions that can be controlled at the nanometer-thickness scale.

Japanese Patent Application No. P2005-171291 reports titanium-based precursors for use in chemical vapor deposition.

European Publication No. 0476671 A2 reports olefins and processes for preparing olefins.

It is beneficial for a precursor to be in liquid state and behave as a single material in the deposition process. The physical nature of some precursors is such that they are solid at ambient temperatures and so less suited to convenient handling and usage for deposition of titanium-containing films, such as TiO₂ and TiN thin-films, in a reproducible manner. Therefore, liquid compositions and methods of liquifying such solid precursors are advantageous for thin film deposition and have advantages for production, handling, storage and transfer of the resulting liquid precursor composition when high volume manufacture and distribution are considered.

### SUMMARY OF THE INVENTION

In one embodiment, a composition for forming a titanium-containing film is provided. The composition comprises at least one precursor selected from the group consisting of (methylcyclopentadienyl)Ti(NMe₂)₃, (ethylcyclopentadienyl)Ti(NMe₂)₃, (isopropylcyclopentadienyl)Ti(NMe₂)₃, (methylcyclopentadienyl)Ti(NEt₂)₃, (methylcyclopentadienyl)Ti(NMeEt)₃, (ethylcyclopentadienyl)Ti(NMeEt)₃ and (methylcyclopentadienyl)Ti(OMe)₃; and at least one cyclopentadienyl-containing liquification co-factor other than the at least one precursor; wherein the at least one cyclopentadienyl-containing liquification co-factor is present in amount sufficient to co-act with the at least one precursor, and in combination with the at least one precursor, forms a liquid composition.

In another embodiment, a composition for forming a titanium-containing film is provided. The composition comprises MeCpTi(NMe₂)₃ and at least one cyclopentadienyl-containing liquification co-factor selected from the group consisting of (MeCpH)₂, MeCpH and a combination thereof, wherein the at least one cyclopentadienyl-containing liquification co-factor is present in the composition from about 0.5% to about 1% to co-act with the MeCpTi(NMe₂)₃ and in combination with the MeCpTi(NMe₂)₃, form a liquid state.

In yet another embodiment, a method to liquify at least one solid precursor for use in a vapor phase deposition process is provided. The at least one solid precursor is selected from the group consisting of (methylcyclopentadienyl)Ti(NMe₂)₃, (ethylcyclopentadienyl)Ti(NMe₂)₃, (isopropylcyclopentadienyl)Ti(NMe₂)₃, (methylcyclopentadienyl)Ti(NEt₂)₃, (methylcyclopentadienyl)Ti(NMeEt)₃, (ethylcyclopentadienyl)Ti(NMeEt)₃ and (methylcyclopentadienyl)Ti(OMe)₃. The method comprises contacting the at least one solid precursor with at least one cyclopentadienyl-containing liquification co-factor other than the at least one precursor to form a liquid composition.

In yet another embodiment, a method to liquify at least about 99% pure solid (methylcyclopentadienyl)Ti(NMe₂)₃ is provided. The method comprises adding at least one cyclopentadienyl-containing liquification co-factor selected from the group consisting of (MeCpH)₂, MeCpH and a combination thereof to the (methylcyclopentadienyl)Ti(NMe₂)₃ to form a liquid composition, wherein the at least one cyclopentadienyl-containing liquification co-factor is added in an amount from about 0.5% to about 1% based on total weight of the liquid composition.

In yet another embodiment, a method to liquify at least about 99% pure solid (methylcyclopentadienyl)Ti(NMe₂)₃ is provided. The method comprises adding a hydrocarbon liquification co-factor having between 7 and 20 carbon atoms in an amount to form a liquid composition, wherein the amount is from about 0.5% to about 5% based on total weight of the liquid composition.

In yet another embodiment, a method to liquify at least about 99% pure solid (methylcyclopentadienyl)Ti(NMe₂)₃ is provided. The method comprises adding toluene to the (methylcyclopentadienyl)Ti(NMe₂)₃ in an amount to form a liquid composition, wherein the toluene is added in an amount from about 0.5% to about 1% based on total weight of the liquid composition.

In yet another embodiment, a method to liquify at least about 99% pure solid (methylcyclopentadienyl)Ti(NMe₂)₃ is provided. The method comprises adding dodecane to the (methylcyclopentadienyl)Ti(NMe₂)₃ in an amount to form a liquid composition, wherein the dodecane is added in an amount from about 1% to about 5% based on total weight of the liquid composition.

In yet another embodiment, a method of forming a titanium-containing film by a vapor deposition process is provided. The method comprises using a liquid precursor composition, wherein the liquid precursor composition comprises (methylcyclopentadienyl)Ti(NMe₂)₃ and at least one cyclopentadienyl-containing liquification co-factor selected from the group consisting of (MeCpH)₂, MeCpH and a combination thereof.

In yet another embodiment, a method of forming a titanium-containing film by a vapor deposition process is provided. The method comprises using a liquid precursor composition, wherein the liquid precursor composition comprises (methylcyclopentadienyl)Ti(NMe₂)₃ and a hydrocarbon liquification co-factor other than (methylcyclopentadienyl)Ti(NMe₂)₃, wherein the hydrocarbon liquification co-factor is present in the composition in amount from about 0.5% to about 5% based on total weight of the liquid precursor composition.

### BRIEF DESCRIPTION OF THE DRAWINGS

FIG. 1 is a graphical representation of thermogravimetric analysis (TGA) data demonstrating weight % vs. temperature/time. The TGA overlay compares TGA data using (1) solid MeCpTi(NMe₂)₃, (2) MeCpTi(NMe₂)₃+MeCp dimer liquid composition, (3) MeCpTi(NMe₂)₃ +dodecane liquid composition.

### DETAILED DESCRIPTION OF THE INVENTION

In various aspects of the invention, compositions and methods are provided to form titanium-containing dielectric thin films.

In a first embodiment, a composition is provided for forming a titanium-containing film comprising at least one precursor selected from the group consisting of (methylcyclopentadienyl)Ti(NMe₂)₃, (ethylcyclopentadienyl)Ti(NMe₂)₃, (isopropylcyclopentadienyl)Ti(NMe₂)₃, (methylcyclopentadienyl)Ti(NEt₂)₃, (methylcyclopentadienyl)Ti(NMeEt)₃, (ethylcyclopentadienyl)Ti(NMeEt)₃ and (methylcyclopentadienyl)Ti(OMe)₃; and at least one liquification co-factor; wherein the at least one liquification co-factor is present in amount sufficient to co-act with the at least one precursor, and in combination with the at least one precursor, forms a liquid composition.

As used herein, the term “precursor” refers to an organometallic molecule, complex and/or compound which is capable of forming a thin film on a substrate by a vapor deposition process such as CVD or ALD. A solid precursor refers to a precursor in a solid state such as a crystalline state or semi-solid state at ambient temperatures and pressures that may or may not remain in this state in the deposition processes delivery system under the higher temperatures employed therein.

The term “Cp” refers to a cyclopentadienyl (C₅H₅) ligand which is bound to a transition metal. As used herein, all five carbon atoms of the Cp ligand are bound to the metal center in η⁵-coordination by π-bonding. Therefore, the precursors of the invention are it complexes.

In one embodiment, the at least one precursor is (methylcyclopentadienyl)Ti(NMe₂)₃.

In some embodiments, only one precursor is present in the composition.

In other embodiments, two or more precursors are present in the composition.

Many potential precursors are solid and less suited to thin film deposition. Therefore, surprisingly, the inventors have found that at least one liquification co-factor, as defined herein, present in the composition co-acts with the at least one precursor to form a liquid state by liquifying the at least one precursor.

A precursor may be solid when it has been prepared to ultra-high purity. Therefore, in one embodiment, the at least one precursor to be liquified is substantially pure. “Substantially pure” refers to the at least one precursor being at least about 99% pure, particularly at least about 99.5% pure. That is, the at least one precursor, has about 1% or less contamination.

As used herein, the term “liquification co-factor” refers to a small amount of chemical additive which is capable of making certain solid precursors, for example high purity solid precursors, into a liquid (i.e. to liquify a solid precursor).

A purpose of a liquification co-factor, as a small amount of chemical additive introduced to a solid precursor, is to provide a liquid source of titanium-containing cyclopentadienyl complex precursors that perform to substantially the same standard as neat solid precursors for use in ALD.

Many prior attempts to overcome the issues related to a solid precursor require the addition of significant amounts of solvent to the solid precursor. In this instance, using significant amounts of solvent results in a final liquid composition that contains very little precursor, for example, particularly less than 50%, less than 30%, less than 10%, and more particularly less than 5% precursor. In the present invention, the ratio is reversed such that, for example, about 97% or more precursor will be present in the final liquid composition. The liquification co-factors of the invention have been found suitable to change certain solid precursors into a liquid state that behaves as a substantially single material in the deposition process.

In some embodiments, the liquification co-factor is a chemical additive which does not affect the expected useable shelf life of the precursor. The expected useable shelf life is typically about 2 years to about 5 years. Therefore, in one embodiment, the at least one co-factor can maintain the liquid composition in a liquid state for substantially the useable shelf life of the liquid composition from initial liquification.

In some embodiments, the liquification co-factor has a volatility and/or vapor pressure similar to the resulting liquid composition. For example, the liquification co-factor may have a volatility and/or vapor pressure lower than and within 5% of the volatility and/or vapor pressure of the solid precursor at a typical usage temperature of around 75° C., particularly within 3% at 75° C., and even more particularly within 2% at 75° C. This can be advantageous so that when using bubbling techniques, compositional changes do not occur that may result in loss of the additive such that the precursor re-solidifies. Therefore, in another embodiment the at least one co-factor can substantially prevent the precursor in the liquid composition from re-solidifying during use with a carrier gas flow in a vapor deposition process. “Substantially prevent” means to prevent an amount of precursor from solidifying where the solidified amount would substantially block pipes used during transfer in a vapor phase deposition process.

Further, a suitable liquification co-factor's atmospheric pressure boiling point corresponds to the temperature at which its vapor pressure is equal to the surrounding atmospheric pressure and it is often called the normal boiling point. For example, the boiling point of MeCpTi(NMe₂)₃ is around 230° C. Therefore, in some instances it can be advantageous for the liquification co-factor to have a boiling point ranging from about 200° C. to about 260° C. For example, diisopropylbenzene has a boiling point of 203° C., Methylcyclopentadiene dimer [(MeCpH)₂] has a boiling point of 200° C. and tetradecane has a boiling point of 252° C., and all may be used in the practice of the invention.

In some embodiments, the liquification co-factor is a material, such as a hydrocarbon material, that is capable of liquifying solid precursors (referred to as a hydrocarbon liquification co-factor). A hydrocarbon liquification co-factor may contain from about 7 to about 20 carbon atoms. For example a hydrocarbon alkane may be used as a hydrocarbon liquification co-factor, such as decane, undecane, tetradecane or dodecane. Alternatively hydrocarbon ring systems may be used, such as toluene, xylene, tetrahydronaphthalene (aka tetralin), decahydronaphthalene (aka decalin), tert-butylbenzene and mesitylene.

In some embodiments, the liquification co-factor is a cyclopentadienyl-containing material that is chemically different from the precursor, such as (MeCpH)₂, MeCpH, (EtCpH)₂, EtCpH, or a combination thereof. As used herein, “Me” refers to methyl and “Et” refers to ethyl.

A variety of different co-factors may be used to form a liquid composition.

In one embodiment, the liquification co-factor is (MeCpH)₂.

In another embodiment, the liquification co-factor is MeCpH.

In another embodiment, the liquification co-factor is toluene.

In another embodiment, the liquificiation co-factor is dodecane.

In another embodiment, the liquification co-factor is a combination of (MeCpH)₂ and MeCpH.

In a particular embodiment, the liquification co-factor is selected from the group consisting of (MeCpH)₂, MeCpH, (EtCpH)₂, EtCpH, toluene, dodecane and any combination thereof.

In some embodiments, only one liquification co-factor is present in the composition.

In other embodiments, two or more liquification co-factors are present in the composition.

The at least one liquification co-factor must be present in the composition in an amount to form a liquid composition. Surprisingly, it has been found that only a small amount of liquification co-factor is necessary to liquify the precursor. Therefore, in one embodiment, the at least one liquification co-factor is present in the composition from about 0.05% to about 5%. In a particular embodiment, the at least one liquification co-factor is present in the composition from about 0.1% to about 3%. And in a further particular embodiment, the at least one liquification co-factor is present in the composition from about 0.5% to about 1%.

In one embodiment, the liquification co-factor is (MeCpH)₂, MeCpH, (EtCpH)₂, EtCpH, toluene or any combination thereof; and the co-factor is present in the composition from about 0.5% to about 1%.

In another embodiment, the liquification co-factor is dodecane and the dodecane is present in the composition from about 1% to about 10%, particularly from about 1% to about 5%.

In a particular embodiment, a composition is provided for forming a titanium-containing film comprising MeCpTi(NMe₂)₃ and at least one liquification co-factor selected from the group consisting of (MeCpH)₂, MeCpH, toluene and any combination thereof, wherein the liquification co-factor is present from 0.5% to about 1% of the composition to co-act with the MeCpTi(NMe₂)₃ and in combination with the MeCpTi(NMe₂)₃ form a liquid state.

In another embodiment, a method to liquify at least one solid precursor selected from the group consisting of (methylcyclopentadienyl)Ti(NMe₂)₃, (ethylcyclopentadienyl)Ti(NMe₂)₃, (isopropylcyclopentadienyl)Ti(NMe₂)₃, (methylcyclopentadienyl)Ti(NEt₂)₃, (methylcyclopentadienyl)Ti(NMeEt)₃, (ethylcyclopentadienyl)Ti(NMeEt)₃ and (methylcyclopentadienyl)Ti(OMe)₃ is provided. The method comprises contacting the at least one solid precursor with at least one cyclopentadienyl-containing liquification co-factor to form a liquid composition.

In one embodiment, the method further comprises either (1) heating the at least one solid precursor before contact with the co-factor or (2) heating the at least one solid precursor and co-factor during and/or after contacting the at least one solid precursor with the co-factor, or (3) both. In a particular embodiment, option 2 is employed and may involve heating the material to a temperature up to the boiling point of either the at least one solid precursor or any one of the at least one co-factors present.

In another embodiment, the method further comprises agitating after contacting the at least one solid precursor with the liquification co-factor to ensure adequate mixing to form a substantially homogenous liquid composition.

In a particular embodiment, the at least one solid precursor is substantially pure as defined above.

In another embodiment, the at least one liquification co-factor has a vapor pressure within about 5% at about 75° C. to the resulting liquid composition, particularly about 3%, and more particularly about 2%.

In another embodiment, the at least one liquification co-factor is a cyclopentadienyl-containing liquification co-factor selected from the group consisting of (MeCpH)₂, MeCpH, (EtCpH)₂, EtCpH and any combination thereof.

In another embodiment, the at least one liquification co-factor is present in the composition from about 0.05% to about 5%, particularly from about 0.1% to about 3% and more particularly from about 0.5% to about 1%.

Thus, in one embodiment, the at least one liquification co-factor is a cyclopentadienyl-containing liquification co-factor such as (MeCpH)₂, MeCpH, (EtCpH)₂, EtCpH and any combination thereof; and the at least one cyclopentadienyl-containing liquification co-factor is present in the composition from about 0.5% to about 1%.

In a particular embodiment, the method is used to liquify (methylcyclopentadienyl)Ti(NMe₂)₃ and the at least one liquification co-factor is the cyclopentadienyl-containing liquification co-factor, MeCpH.

In another embodiment, the method is used to liquify (methylcyclopentadienyl)Ti(NMe₂)₃ and the at least one liquification co-factor is the cyclopentadienyl-containing liquification co-factor, (MeCpH)₂.

In a particular embodiment, the method further comprises contacting the at least one solid precursor with toluene to form the liquid composition. For example, from about 2% to about 5% toluene may be used in addition to the cyclopentadienyl-containing liquification co-factor to help liquify the precursor.

In another embodiment, a method to liquify about 99% pure solid (methylcyclopentadienyl)Ti(NMe₂)₃ is provided. The method comprises adding at least one cyclopentadienyl-containing liquification co-factor selected from the group consisting of (MeCpH)₂, MeCpH and a combination thereof to the (methylcyclopentadienyl)Ti(NMe₂)₃ to form a liquid composition, wherein the at least one cyclopentadienyl-containing liquification co-factor is added in an amount from about 0.5% to about 1% based on total weight of the liquid composition.

In yet another embodiment, a method to liquify about 99% pure solid (methylcyclopentadienyl)Ti(NMe₂)₃, the method comprising adding a hydrocarbon liquification co-factor having between 7 and 20 carbon atoms in an amount to form a liquid composition, wherein the amount is from about 0.5% to about 5% based on total weight of the liquid composition.

In yet another embodiment, a method to liquify about 99% pure solid (methylcyclopentadienyl)Ti(NMe₂)₃ is provided, the method comprising adding toluene to the (methylcyclopentadienyl)Ti(NMe₂)₃ in an amount to form a liquid composition, wherein the toluene is added in an amount from about 0.5% to about 1% based on total weight of the liquid composition.

In yet another embodiment, a method to liquify about 99% pure solid (methylcyclopentadienyl)Ti(NMe₂)₃ is provided, the method comprising adding dodecane to the (methylcyclopentadienyl)Ti(NMe₂)₃ in an amount to form a liquid composition, wherein the dodecane is added in an amount from about 1% to about 5% based on total weight of the liquid composition.

In another embodiment of the invention, a method of forming a titanium-containing film by a vapor deposition process is provided. The method comprises delivering a liquid precursor composition to a substrate, wherein the liquid precursor composition comprises a precursor selected from the group consisting of (methylcyclopentadienyl)Ti(NMe₂)₃, (ethylcyclopentadienyl)Ti(NMe₂)₃, (isopropylcyclopentadienyl)Ti(NMe₂)₃, (methylcyclopentadienyl)Ti(NEt₂)₃, (methylcyclopentadienyl)Ti(NMeEt)₃, (ethylcyclopentadienyl)Ti(NMeEt)₃ and (methylcyclopentadienyl)Ti(OMe)₃; and at least one cyclopentadienyl-containing liquification co-factor selected from the group consisting of (MeCpH)₂, MeCpH, (EtCpH)₂, EtCpH and any combination thereof.

In a particular embodiment, the liquid precursor composition to form the titanium-containing film further comprises toluene to liquify the precursor. For example, from about 2% to about 5% toluene may also be added to help liquify the precursor.

In another particular embodiment, a method is provided to form a titanium-containing film by a vapor deposition process, the method comprising delivering a liquid precursor composition to a substrate, where the liquid precursor comprises (methylcyclopentadienyl)Ti(NMe₂)₃ and a hydrocarbon liquification co-factor, wherein the hydrocarbon liquification co-factor is present in the composition in amount from about 0.5% to about 5% based on total weight of the liquid precursor composition. Examples of such hydrocarbon liquification co-factors have been discussed previously, such as toluene and dodecane.

As used herein, the term “high-κ dielectric” refers to a material, such as a titanium-containing film, with a higher dielectric constant (κ) when compared to silicon dioxide (which has a dielectric constant of about 3.7). Typically, a high-κ dielectric film is used in semiconductor manufacturing processes to replace the silicon dioxide gate dielectric. A high-κ dielectric film may be referred to as having a “high-κ gate property” when the dielectric film is used as a gate material and has at least a higher dielectric constant than silicon dioxide.

As used herein, the term “relative permittivity” is synonymous with dielectric constant (κ).

As used herein, the term “vapor deposition process” is used to refer to any type of vapor deposition technique such as CVD or ALD. In various embodiments of the invention, CVD may take the form of liquid injection CVD. In other embodiments, ALD may be either photo-assisted ALD or liquid injection ALD.

The vapor deposition processes of the invention, such as ALD and CVD, can be used to form various titanium-containing thin films, such as metal or metal oxide films, on substrates using at least one of the organometallic precursors mentioned herein, particularly (methylcyclopentadienyl)Ti(NMe₂)₃. The film can be formed by the liquid precursor composition independently or in combination with a co-reactant (can be referred to as co-precursor). Examples of such co-reactants include, but are not limited to hydrogen, hydrogen plasma, oxygen, air, water, ammonia, hydrazine, alkylhydrazine, borane, silane, ozone or any combination thereof.

In one embodiment, the liquid precursor composition is delivered to the substrate in pulses alternating with pulses of an oxygen source to create a metal oxide film. Examples of such oxygen sources include, without limitation, H₂O, O₂ or ozone.

A variety of substrates can be used in the methods of the present invention. For example, the liquid precursor composition may be delivered for deposition on substrates such as, but not limited to, silicon, silicon oxide, silicon nitride, tantalum, tantalum nitride, or copper.

The ALD and CVD methods of the invention encompass various types of ALD and CVD processes such as, but not limited to, conventional processes, liquid injection processes and photo-assisted processes.

In one embodiment, conventional CVD is used to form a metal-containing thin film using the liquid precursor composition. For conventional CVD processes, see for example Smith, Donald (1995). Thin-Film Deposition: Principles and Practice. McGraw-Hill.

In another embodiment, liquid injection CVD is used to form a metal-containing thin film the liquid precursor composition.

Examples of liquid injection CVD growth conditions include, but are not limited to:
(1) Substrate temperature: 200-600° C. on Si(100)
(2) Evaporator temperature: about 200° C.
(3) Reactor pressure: about 5 mbar
(4) Liquid precursor: Solid precursor with co-factor
(5) Injection rate: about 30 cm³ hr⁻¹
(6) Argon flow rate: about 200 cm³ min⁻¹
(7) Oxygen flow rate: about 100 cm³ min⁻¹
(8) Run time: 10 min

In another embodiment, photo-assisted CVD is used to form a metal-containing thin film using the liquid precursor composition.

In a further embodiment, conventional ALD is used to form a metal-containing thin film using the liquid precursor composition. For conventional and/or pulsed injection ALD process see for example, George S. M., et. al. J. Phys. Chem. 1996. 100:13121-13131.

In another embodiment, liquid injection ALD is used to form a metal-containing thin film using the liquid precursor composition, wherein the liquid precursor composition is delivered to the reaction chamber by direct liquid injection as opposed to vapor draw by a bubbler. For liquid injection ALD process see, for example, Potter R. J., et. al. Chem. Vap. Deposition. 2005. 11(3):159.

Examples of liquid injection ALD growth conditions include, but are not limited to:
(1) Substrate temperature: 160-300° C. on Si(100)
(2) Evaporator temperature: about 175° C.
(3) Reactor pressure: about 5 mbar
(4) Liquid precursor: Solid precursor with co-factor
(5) Injection rate: about 2.5 μl pulse⁻¹ (4 pulses cycle⁻¹)
(6) Inert gas flow rate: about 200 cm³ min⁻¹
(7) Pulse sequence (sec.) (precursor/purge/H₂O/purge): will vary according to chamber size.
(8) Number of cycles: will vary according to desired film thickness.

In one embodiment, the liquid precursor composition is used to form a titanium-containing film by liquid injection ALD, wherein the liquid precursor composition is used neat as the injection material. This can be used to access high growth rates and remove excess solvent requirements.

In another embodiment, photo-assisted ALD is used to form a metal-containing thin film using the liquid precursor composition. For photo-assisted ALD processes see, for example, U.S. Pat. No. 4,581,249.

In another embodiment, both liquid injection and photo-assisted ALD may be used to form a titanium-containing film using a liquid precursor composition described herein.

In another embodiment, plasma-assisted ALD may be used to form a titanium-containing film using a liquid precursor composition described herein.

The methods of the invention can be used to form a variety of titanium-containing films using the liquid precursor composition. In a particular embodiment, a titanium, titanium oxide or titanium nitride film is formed by ALD.

In another embodiment, a method is provided for forming a “mixed” metal film by a vapor deposition process by delivering for deposition the liquid precursor composition and at least one non-titanium precursor. For example, the liquid precursor composition and at least one appropriate non-titanium precursor, such as a lead, hafnium, zirconium, strontium and/or barium precursor may be delivered for deposition to a substrate to create a “mixed” metal film. For example, in a particular embodiment, the liquid precursor composition of the invention can be used with a non-titanium precursor to form a metal titanate film, such as a strontium titanate, barium titanate or lead zirconate titanate (PZT) film.

In a particular embodiment, the liquid precursor composition can be used to dope a metal oxide film, such as but not limited to a hafnium-containing oxide film, a zirconium-containing oxide film, a lanthanide-containing oxide film or any combination thereof. As used herein, when the liquid precursor composition is used to dope a metal oxide film, the titanium may be substitutional or interstitial on the film-forming lattice.

In another particular embodiment, the liquid precursor composition can be used to form a ferroelectric, lead zirconate titanate (PZT) film.

A thin film created by a method of the invention can have a permittivity of between 10 and 250, preferably at least 25 to 40 and more preferably at least 40 to 100. Further, an ultra high permittivity can be considered to be a value higher than 100. It is understood by one of ordinary skill in the art that the resulting permittivity of the film depends on a number of factors, such as the metal(s) used for deposition, the thickness of the film created, the parameters and substrate employed during growth and subsequent processing.

In a particular embodiment, the liquid precursor composition can be used to form a film with an ultra high permittivity (high-κ) of over 100.

In particular embodiments, the methods of the invention are utilized for applications such as dynamic random access memory (DRAM) and complementary metal oxide semi-conductor (CMOS) for memory and logic applications, on substrates such as silicon chips.

### EXAMPLES

The following examples are merely illustrative, and do not limit this disclosure in any way. All manipulations were carried out in an inert atmosphere using a glove box and Schlenk line techniques. Air- and moisture-sensitive substances were handled under inert atmosphere using Schlenk technique. Nitrogen was used as inert gas. All Schlenk glass wear was acid washed and rinsed with acetone before drying in an oven at 80° C. overnight.

All chemicals were bought from Sigma-Aldrich® and used without purification. MeCpH was cracked to its monomer at distillate temperature 80° C. All solvent bottles were pre-purged with nitrogen before use.

NMR analysis was carried out using a Bruker 250 MHz machine.

### Example 1

### 1. Crude Liquid Product Preparation

In a glove box Ti(NMe₂)₄ (896 g, 4.0 moles) was measured out into a Schlenk. This was then transferred via catheter to a 5 Lt round bottom flask. Anhydrous toluene (2 Lt) was then transferred via catheter into the same flask. Cracked MeCpH (160 g, 2.0moles) was added over about 2 hours at room temperature. The reaction was then gradually heated to reflux, going from about 60° C. up to about 100° C. and then refluxed overnight. The flask was left to cool (<40° C.). A second batch of cracked MeCpH (160 g, 2.0 moles) was added over about 2 hours, again the reaction was gradually heated to reflux, going from 60° C. up to about 100° C. and then refluxed overnight. Solvent was removed via trap-trap under vacuum 40° C. (about 1 Torr).

NMR integration of different runs showed peaks as expected 5.8 ppm, (m, 2H, C₅H₄), 5.68 ppm, (m, 2H, C₅H₄), 3.05 ppm, (s, 18H, N(CH₃)₂), and 2.0ppm, (s, 3H, CH₃-C₅H₄) although slight variations in the integration values were observed.

| Prep No | Me-Cp | NMe₂ | Comments |
|---|---|---|---|
| LKR130 | 1 | 3.38 | Liquid product as |
| | | | prepared, without |
| | | | distillation |
| LKR125 | 1 | 3.57 | Liquid product as |
| | | | prepared, without |
| | | | distillation |

2. Product Purification and Subsequent Liquification (1)

The resulting liquid product obtained as detailed above was purified using high vacuum distillation at 90-115° C. (about 0.5 Torr) resulting in a 95% yield divided into three fractions, dark red liquid (428 g), dark red liquid (472 g) and a dark red waxy resin 171 g (mp 75-80° C.). Due to the different physical states of the fractions and the desire to have a homogeneous liquid product all the fractions were recombined using Schlenk techniques to form a dark red solid/liquid slurry. The whole was warmed to 80° C. prior to adding freshly cracked MeCpH (5 g, 0.06 moles, 0.5%) over about 15 minutes and the resulting mixture held at elevated temperature for an hour. On standing and cooling the fraction remained liquid.

| Prep No | Me-Cp | NMe₂ | Comments |
|---|---|---|---|
| LKR118 | 1 | 3.69 | Combined fractions |
| | | | spiked with some |
| | | | MeCp-H (0.5%) to |
| | | | form liquid product |

### 3. Product Purification and Subsequent Liquification (2)

The production and purification of MeCpTi(NMe₂)₃ was performed as above yielding a total of 950 g in three fractions (two solid and one liquid). Due to the prevalence of solid product and the desire to have a homogeneous liquid product all the fractions were recombined using Schlenk techniques to form a dark red solid/liquid slurry. The whole was warmed to 80° C. prior to adding freshly cracked MeCpH (28 g, 0.3 moles, 3%) over about 15 minutes and the resulting mixture held at elevated temperature for an hour. On standing and cooling the fraction remained liquid.

| Prep No | Me-Cp | NMe₂ | Comments |
|---|---|---|---|
| SH36 | 1 | 3.00 | Combined fractions |
| | | | spiked with some |
| | | | MeCp-H (3%) to |
| | | | form liquid product |

### Example 2

### Spiking MeCpTi(NMe₂)₃ with (MeCpH)₂ Dimer

From crude liquid material supplied via LKR125, a turbo vac distillation was carried out, and the solid fraction isolated. From this, a spiking experiment was carried out to see what percentage of uncracked (MeCpH)₂ would be needed to encourage the sample to liquify. In the glovebox dopak bottles were charged with MeCpTi(NMe₂)₃ (1 g, 3.86×10⁻³ mol). Spiking with 1% (0.01 g, 6.23×10⁻⁵ mol), 2% (0.02 g, 1.24×10⁻⁴ mol), 3% (0.03 g, 1.87×10⁻⁴ mol), 4% (0.04 g, 2.50×10⁻⁴ mol) and 5% (0.05 g, 3.12×10⁻⁴ mol) (MeCpH)₂ dimer was carried out by simple addition and hand shaking to ensure good mixing. The samples were left overnight and ¹H NMR recorded.

| Prep No | NMe₂ | Me-Cp | Comments |
|---|---|---|---|
| SLH 44 | 1 | 0.285 | Solid fraction isolated |
| | | | on turbo vac. |
| SLH 44 | 1 | 0.290 | Solid fraction with |
| | | | 1% (MeCpH)₂ dimer. |
| | | | Became Liquid. |
| SLH 44 | 1 | 0.300 | Solid fraction with |
| | | | 2% (MeCpH)₂ dimer. |
| | | | Became Liquid |
| SLH 44 | 1 | 0.315 | Solid fraction with |
| | | | 3% (MeCpH)₂ dimer. |
| | | | Became Liquid |
| SLH 44 | 1 | 0.310 | Solid fraction with |
| | | | 4% (MeCpH)₂ dimer. |
| | | | Became Liquid |
| SLH 44 | 1 | 0.315 | Solid fraction with |
| | | | 5% (MeCpH)₂ dimer. |
| | | | Became Liquid |

Conclusion is that addition of small amounts of (MeCpH)₂ dimer result in complete liquification of solid MeCpTi(NMe₂)₃ product. As little as 1% achieves this objective.

### Example 3

### Spiking MeCpTi(NMe₂)₃ with MeCpH Monomer

From crude liquid material supplied via LKR125, a turbo vac distillation is carried out, and the solid fraction isolated. From this, a spiking experiment was carried out to see what percentage of cracked MeCpH monomer would be needed to encourage the sample to liquify. In the glovebox dopak bottles were charged with MeCpTi(NMe₂)₃ (1 g, 3.86×10⁻³ mol). Spiking with 1% (0.01 g, 1.24×10⁻⁴ mol), 2% (0.02 g, 2.46×10⁻⁴ mol), 3% (0.03 g, 3.70×10⁻⁴ mol), 4% (0.04 g, 4.93×10⁻⁴ mol) and 5% (0.05 g, 6.17×10⁻⁴ mol) MeCpH monomer was carried out by simple addition and hand shaking to ensure good mixing. The samples were left overnight and ¹H NMR recorded.

| Prep No | NMe₂ | Me-Cp | Comments |
|---|---|---|---|
| SLH 44 | 7.04 | 0.285 | Solid fraction isolated |
| | | | on turbo vac. |
| SLH 44 | 7.45 | 0.305 | Solid fraction with |
| | | | 1% MeCpH |
| | | | monomer. Became |
| | | | semi-solid. |
| SLH 44 | 6.87 | 0.325 | Solid fraction with |
| | | | 2% MeCpH |
| | | | monomer. |
| | | | Became semi-solid. |
| SLH 44 | 6.25 | 0.360 | Solid fraction with |
| | | | 3% MeCpH |
| | | | monomer. |
| | | | Became Liquid |
| SLH 44 | 6.43 | 0.345 | Solid fraction with |
| | | | 4% MeCpH |
| | | | monomer. |
| | | | Became Liquid |
| SLH 44 | 6.29 | 0.355 | Solid fraction with |
| | | | 5% MeCpH |
| | | | monomer. |
| | | | Became Liquid |

Conclusion is that addition of small amounts of MeCpH monomer result in complete liquification of solid MeCpTi(NMe₂)₃ product. As little as 1% achieves this objective which is slightly more than is needed of the (MeCpH)₂ dimer to perform this function.

### Example 4

### Spiking MeCpTi(NMe₂)₃ with Toluene

From crude liquid material supplied via LKR125, a turbo vac distillation was carried out, and the solid fraction isolated. From this, a spiking experiment was carried out to see what percentage of toluene would be needed to encourage the sample to liquify. In the glovebox dopak bottles were charged with MeCpTi(NMe₂)₃ (1 g, 3.86×10⁻³ mol). Spiking with 1% (0.01 g, 1.09×10⁻⁴ mol), 2% (0.02 g, 2.17×10⁻⁴ mol), 3% (0.03 g, 3.26×10⁻⁴ mol), 4% (0.04 g, 4.35×10⁻⁴ mol) and 5% (0.05 g, 5.43×10⁻⁴ mol) toluene was carried out by simple addition and hand shaking to ensure good mixing. The samples are left overnight and and ¹H NMR recorded.

| Prep No | NMe₂ | Me-Cp | Comments |
|---|---|---|---|
| SLH 44 | 7.04 | 0.290 | Solid fraction isolated |
| | | | on turbo vac. |
| SLH 44 | 6.80 | 0.320 | Solid fraction with |
| | | | 1% toluene. Liquid. |
| SLH 44 | 6.54 | 0.335 | Solid fraction with |
| | | | 2% toluene. Liquid. |
| SLH 44 | 6.65 | 0.320 | Solid fraction with |
| | | | 3% toluene. Liquid. |
| SLH 44 | 7.16 | 0.305 | Solid fraction with |
| | | | 4% toluene. Liquid. |
| SLH 44 | 7.08 | 0.315 | Solid fraction with |
| | | | 5% toluene. Liquid. |

Conclusion is that addition of small amounts of toluene result in complete liquification of solid MeCpTi(NMe₂)₃ product. As little as 1% achieves this objective in line with the (MeCpH)₂ dimer.

### Example 5

### Spiking MeCpTi(NMe₂)₃ with Dodecane

In a glove box 11 g of the solid MeCpTi(NMe₂)₃ was placed into a small schlenk labelled dodecane. Into another schlenk labelled MeCp was added 10 g MeCpTi(NMe₂)₃. Both vessels where then transferred to the fume cupboard. Using an oil bath both shlenks where heated with an oil bath to 80° C. to melt the solid. A small amount of dodecane was added to one schlenk and a small amount of MeCp dimer was added to the other. Both samples were left to stir for two minutes before being removed from the oil bath and allowed to cool to 25° C. Both samples became a solid at 28-32° C. The above was repeated until enough ligand was added to cause the MeCpTi(NMe₂)₃ to be liquid at room temperature. See table below.

| | Dodecane | MeCp added | |
|---|---|---|---|
| | added (g) | (g) | |
| | 0.163 | | 0.22 |
| | 0.156 | | 0.231 |
| | 0.197 | | 0.12 |
| Total | 0.516 | Total | 0.571 |
| | 4.69% | | 5.70% |

Dodecane caused solid MeCpTi(NMe₂)₃ to become a liquid at room temperature when present above 4.7% w/w. This is 1% lower than what is required by MeCp. Dodecane can be used to convert MeCpTi(NMe₂)₃ to a liquid at room temperature at lower impurity levels than previously used MeCp dimer. NMR indicates that it has no direct affect on the arrangement of the compound.

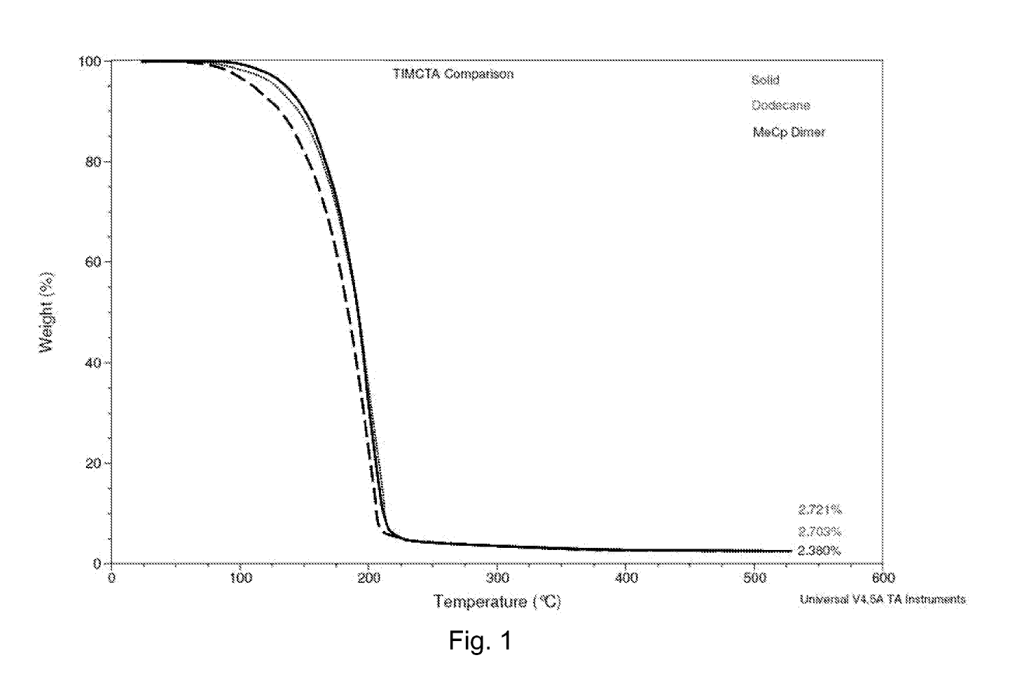

Residuals for all samples in TGA have been below 3%. See FIG. 1. The onset of decomposition for the MeCp derivative is approximately 65° C. This is 16.25° C. less than the onset of the solid, and similarly, the dodecane derivatives that start at approximately 82° C. The MeCp seems to decompose at around 10° C. less than the solid sample up to 210° C. after which the TGA curve starts to level out and results in 2.7% residue. The dodecane sample offsets at the same time as the solid but tends to initially decompose at a faster rate up to 175° C. at which point it is decomposing at an equal rate as that of the solid and results in an equal residue of 2.7%. All sample start to level out at equal temperature, ˜225° C. TGA analysis indicates that addition of MeCp to the solid precursor causes a 10° C. less stable compound compared to the pure solid. This is also reflected in the lower residues suggesting a more easily lost volatile MeCp over the course of the analysis. The stability of MeCpTi(NMe₂)₃ with the dodecane additive behaves almost equal to the pure solid which is represented by equal residuals in both samples.

### Example 6

### ALD using (MeCp)Ti(NMe₂)₃+(MeCpH) Liquid Composition

Titanium oxide thin films were deposited in a custom-built ALD reactor. Liquid composition containing (MeCp)Ti(NMe₂)₃ and MeCpH, as prepared in example 1, and ozone were used as precursors. The titanium oxide films were deposited on silicon wafer substrates. Prior to deposition, the wafer substrates were prepared by dicing the wafer (1 inch×½ inch), and 1% HF polished.

The growth temperature was 200-350° C. The growth pressure was 0.5-1.5 Torr. The reactor was continuously purged with 30 sccm of dry nitrogen. All the computer controlled valves in the reactor were the air operated ALD VCR valves from Cajon.

Ozone was purged in excess. The titanium was stored in a stainless steel ampoule. Attached directly to the ampoule was an ALD valve. The output of this ALD valve was Tee'd with another ALD valve used for nitrogen injection. The Tee outlet leg was connected to a 500 cm³ stainless steel reservoir. The outlet of the reservoir was attached to a third ALD valve, called the inject valve, whose outlet goes directly to the reactor. Nitrogen injection was used to build up the total pressure behind the titanium inject valve so that the pressure was higher than the reactor growth pressure. The injected nitrogen was accomplished using a 30 micron pin hole VCR gasket. All of the valves and ampoule were placed into an oven-like enclosure that allowed the ampoule, valves, and tubing to be heated uniformly to 50° C. to 250° C.

During the ALD growth operation, the valves were sequenced in the following manner. The titanium precursor was introduced to the activated silicon surface. A nitrogen purge then took place which included evacuation to remove surplus reactant molecules not attached to the surface. Ozone was then introduced as a co-reactant species, followed by an additional purge with nitrogen. The ozone was then injected to start the ALD cycle all over again.

The total amount of cycles was from 100 to 400, typically 300. Results showed that the deposition rate was independent of the titanium dose as varied through its vapor pressure, which in turn was varied through its evaporation temperature. This proves that the film growth proceeded in a self-limiting manner as is characteristic of ALD.

All patents and publications cited herein are incorporated by reference into this application in their entirety.

The words “comprise”, “comprises”, and “comprising” are to be interpreted inclusively rather than exclusively.

1. A composition for forming a titanium-containing film comprising at least one precursor selected from the group consisting of (methylcyclopentadienyl)Ti(NMe₂)₃, (ethylcyclopentadienyl)Ti(NMe₂)₃, (isopropylcyclopentadienyl)Ti(NMe₂)₃, (methylcyclopentadienyl)Ti(NEt₂)₃ and (methylcyclopentadienyl)Ti(OMe)₃; and at least one cyclopentadienyl-containing liquification co-factor other than the at least one precursor; wherein the at least one cyclopentadienyl-containing liquification co-factor is present in amount sufficient to co-act with the at least one precursor, and in combination with the at least one precursor, forms a liquid composition.

2. The composition of claim 1, wherein the at least one precursor is (methylcyclopentadienyl)Ti(NMe₂)₃.

3. The composition of claim 1, wherein the at least one cyclopentadienyl-containing liquification co-factor has a vapor pressure lower than and within about 5% at 75° C. to the resulting liquid composition.

4. (canceled)

5. The composition of claim 1, wherein the at least one cyclopentadienyl-containing liquification co-factor is selected from the group consisting of (MeCpH)₂, MeCpH, (EtCpH)₂, EtCpH and combination thereof.

6. The composition of claim 1, wherein the at least one cyclopentadienyl-containing liquification co-factor is present in the composition from about 0.05% to about 5%.

7-10. (canceled)

11. A method to liquify at least one solid precursor for use in a vapor phase deposition process selected from the group consisting of (methylcyclopentadienyl)Ti(NMe₂)₃, (ethylcyclopentadienyl)Ti(NMe₂)₃, (isopropylcyclopentadienyl)Ti(NMe₂)₃, (methylcyclopentadienyl)Ti(NEt₂)₃, (methylcyclopentadienyl)Ti(NMeEt)₃, (ethylcyclopentadienyl)Ti(NMeEt)₃ and (methylcyclopentadienyl)Ti(OMe)₃; the method comprising
contacting the at least one solid precursor with at least one cyclopentadienyl-containing liquification co-factor other than the at least one precursor to form a liquid composition.

12. The method of claim 11, wherein the at least one solid precursor is at least about 99.5% pure.

13-14. (canceled)

15. The method of claim 11, wherein the at least one cyclopentadienyl-containing liquification co-factor has a vapor pressure within about 5% at 75° C. to the resulting liquid composition.

16. (canceled)

17. The method of claim 11, wherein the at least one cyclopentadienyl-containing liquification co-factor is selected from the group consisting of (MeCpH)₂, MeCpH, (EtCpH)₂, EtCpH and combination thereof.

18. The method of claim 11, wherein the at least one cyclopentadienyl-containing liquification co-factor is present in the composition from about 0.05% to about 5%.

19-20. (canceled)

21. The method of claim 11, wherein the at least one cyclopentadienyl-containing liquification co-factor is selected from the group consisting of (MeCpH)₂, MeCpH and combination thereof; and the at least one cyclopentadienyl-containing liquification co-factor is present in the composition from about 0.5% to about 1%.

22. The method of claim 11, wherein the at least one solid precursor is (methylcyclopentadienyl)Ti(NMe₂)₃.

23-24. (canceled)

25. The method of claim 11, further comprising contacting the at least one solid precursor with toluene to form the liquid composition.

26. The method of claim 11, wherein the at least one cyclopentadienyl-containing liquification co-factor maintains the liquid composition in a liquid state for substantially the useable shelf life of the liquid composition from initial liquification.

27. The method of claim 11, wherein the at least one cyclopentadienyl-containing liquification co-factor substantially prevents the precursor in the liquid composition from re-solidifying during use with a carrier gas flow in the vapor deposition process.

28. (canceled)

29. A method to liquify at least about 99% pure solid (methylcyclopentadienyl)Ti(NMe2)3, the method comprising adding a hydrocarbon liquification co-factor having between 7 and 20 carbon atoms in an amount to form a liquid composition, wherein the amount of hydrocarbon liquification co-factor present is from about 0.5% to about 5% based on total weight of the liquid composition.

30. A method to liquify at least about 99% pure solid (methylcyclopentadienyl)Ti(NMe₂)₃, the method comprising adding toluene to the (methylcyclopentadienyl)Ti(NMe₂)₃ in an amount to form a liquid composition, wherein the amount of toluene present is from about 0.5% to about 1% based on total weight of the liquid composition.

31. (canceled)

32. A method of forming a titanium-containing film by a vapor deposition process, the method comprising using a liquid precursor composition, wherein the liquid precursor composition comprises (methylcyclopentadienyl)Ti(NMe₂)₃ and at least one cyclopentadienyl-containing liquification co-factor selected from the group consisting of (MeCpH)₂, MeCpH and combination thereof.

33. The method of claim 32, where the at least one cyclopentadienyl-containing liquification co-factor is present in the liquid precursor composition from about 0.5% to about 1.0%.

34. The method of claim 32, wherein the vapor deposition process is chemical vapor deposition.

35. (canceled)

36. The method of claim 32, wherein the vapor deposition process is atomic layer deposition.

37-46. (canceled)
